(19) United States
(12) Patent Application Publication
(10) Pub. No.: US 2024/0274336 A1
(43) Pub. Date: Aug. 15, 2024

(54) SUPERCONDUCTING SWITCH FOR A SUPERCONDUCTING MAGNET

(71) Applicant: General Electric Company, Schenectady, NY (US)

(72) Inventors: Mark Ernest Vermilyea, Niskayuna, NY (US); Anbo Wu, Clifton Park, NY (US); Susumu Mine, Kanagawa (JP); Minfeng Xu, Ballston Lake, NY (US)

(21) Appl. No.: 18/567,982

(22) PCT Filed: Jun. 11, 2021
(86) PCT No.: PCT/US2021/036982

§ 371 Date: Dec. 7, 2023

(51) Int. Cl. H01F 6/04

(52) U.S. Cl. CPC H01F 6/04

(57) ABSTRACT

A superconducting magnet includes a cooling tank containing a cooling medium and at least one superconducting circuit configured for generating a magnetic field. The superconducting magnet further includes a power supply connected to the superconducting circuit(s) for energizing the superconducting circuit(s) and a superconducting switch electrically connected across ends of the superconducting circuit(s). The superconducting switch includes a superconducting winding and a thermal conduction member having a first end thermally coupled to the superconducting winding and a second end thermally coupled to the cooling medium within the cooling tank. The thermal conduction member includes, at least, a first layer and a second layer. The first layer is constructed of a metal material having a first thermal conductivity. The second layer supports the first layer and is constructed of a material having a second thermal conductivity that is lower than the first thermal conductivity.

### FIELD

The present disclosure relates to superconducting magnets, and more particularly, to improved superconducting switches for superconducting magnets.

### BACKGROUND

A superconducting magnet is an electromagnet made from coils of superconducting circuit. In its superconducting state, the superconducting circuit has no electrical resistance and therefore can conduct much larger electric currents than ordinary wire, creating intense magnetic fields. Thus, superconducting magnets can produce greater magnetic fields than all but the strongest non-superconducting electromagnets and can be cheaper to operate because no energy is dissipated as heat in the windings. Accordingly, superconducting magnets are commonly used in magnetic resonance imaging (MRI) machines and in scientific equipment such as nuclear magnetic resonance (NMR) spectrometers, generators, mass spectrometers, fusion reactors, and particle accelerators.

During operation, the superconducting magnet windings must be cooled below their critical temperature, the temperature at which the winding material changes from the normal resistive state and becomes a superconductor. Typically, the windings are cooled to temperatures significantly below their critical temperature, because the lower the temperature, the better superconductive windings work—the higher the currents and magnetic fields they can stand without returning to their non-superconductive state. Thus, two types of cooling regimes are commonly used to maintain the magnet windings at temperatures sufficient to maintain superconductivity, i.e., liquid cooling and mechanical cooling. In liquid cooling, liquid helium is used as a coolant, which has a boiling point of 4.2 Kelvin that is far below the critical temperature of most winding materials. Thus, the superconducting magnet and the liquid helium are contained in a thermally insulated container called a cryostat. Alternatively, the superconducting magnet may be cooled using two-stage mechanical refrigeration.

In one operating mode of the superconducting magnet, the windings can be short-circuited with a piece of superconducting material once the magnet has been energized. The short circuit is made by a switch, sometimes referred to as a persistent switch, which generally refers to the piece of superconducting material inside the magnet connected across the winding ends and attached to a small heater. Thus, the windings become a closed superconducting loop, the power supply can be turned off, and persistent currents will flow for long periods of time, preserving the magnetic field. The advantage of this persistent mode is that stability of the magnetic field is better than is achievable with the best power supplies, and no energy is needed to power the windings.

Accordingly, when the magnet is first turned on, the switch is heated above its transition temperature, such that the switch is resistive. To operate in the persistent mode, the supply current is adjusted until the desired magnetic field is obtained, then the heater is turned off. The persistent switch cools to its superconducting temperature, thereby short-circuiting the windings. Then, the power supply can be turned off.

Conventional refrigeration cooling, which uses tubes filled with liquid helium to cool the windings, however, utilizes much more liquid helium during ramp up and parking for the switch than liquid cooling.

Thus, the present disclosure is directed to an improved superconducting switch for a superconductive circuit that is cooled by conduction to a liquid helium circuit. More specifically, the switch has thermal conductance properties that are optimized for the desired switch operating temperature to minimize the amount of liquid helium that is boiled off during the magnet ramp up and parking steps.

### BRIEF DESCRIPTION

Aspects and advantages of the present disclosure will be set forth in part in the following description, or may be obvious from the description, or may be learned through practice of the present disclosure.

In one aspect, the present disclosure is directed to a superconducting magnet. The superconducting magnet includes a cooling tank containing a cooling medium and at least one superconducting circuit configured for generating a magnetic field. The superconducting magnet further includes a power supply connected to the superconducting circuit(s) for energizing the superconducting circuit(s) and a superconducting switch electrically connected across ends of the superconducting circuit(s). The superconducting switch includes a superconducting winding and a thermal conduction member having a first end thermally coupled to the superconducting winding and a second end thermally coupled to the cooling medium within the cooling tank. The thermal conduction member includes, at least, a first layer and a second layer. The first layer is constructed of a metal material having a first thermal conductivity. The second layer supports the first layer and is constructed of a material having a second thermal conductivity that is lower than the first thermal conductivity.

In an embodiment, the superconducting winding of the superconducting switch may be a bi-filar wound superconducting winding. In another embodiment, a coefficient of thermal expansion (CTE) of the second layer is substantially equal to the CTE of the first layer, e.g., within plus or minus 10%.

In further embodiments, the second layer has a higher tensile strength than the first layer. In another embodiment, the second layer is bonded to the first layer using an epoxy resin.

In additional embodiments, the metal material of the first layer is constructed of a high-purity metal material with a purity of greater than 99.99%. For example, in an embodiment, the high-purity metal material may be annealed, high-purity aluminum. In alternative embodiments, the first layer is constructed of tungsten or platinum.

In another embodiment, the material of the second layer is an alloy of the metal material of the first layer.

In certain embodiments, the first thermal conductivity of the first layer in a first temperature range of less than 40 Kelvin is at least three times greater than the first thermal conductivity of the first layer in a second temperature range of greater than 50 Kelvin. In such embodiments, the second temperature range includes temperatures when the superconducting switch is maintained electrically resistive during an initial phase of a magnet energization process. In another embodiment, the first temperature range includes temperatures equal to about one third to one half of the second temperature range.

In several embodiments, the superconducting switch is electrically connected in series with the superconducting circuit(s).

In further embodiments, the superconducting switch may further include one or more leads electrically connected with current leads. In such embodiments, the current leads are electrically connected with the power supply during an energization process.

In yet another embodiment, the superconducting magnet is part of a magnetic resonance imaging (MRI) machine or a generator.

In another aspect, the present disclosure is directed to a superconducting switch for electrically connecting ends of at least one superconducting circuit of a superconducting magnet. The superconducting switch includes a superconducting winding and a thermal conduction member having a first end thermally coupled to the superconducting winding and a second end thermally coupled to a cooling tank. The thermal conduction member includes, at least, a first layer and a second layer. The first layer is constructed of a metal material having a first thermal conductivity. The second layer supports the first layer and is constructed of a material having a second thermal conductivity that is lower than the first thermal conductivity.

In yet another aspect, the present disclosure is directed to a method of energizing a superconducting magnet having a superconducting switch. The superconducting switch includes a superconducting winding and a thermal conduction member having a first end thermally coupled to the superconducting winding and a second end thermally coupled to the cooling tank. The thermal conduction member includes, at least, a first layer and a second layer. The first layer is constructed of a metal material having a first thermal conductivity. The second layer supports the first layer and is constructed of a material having a second thermal conductivity that is lower than the first thermal conductivity. The method includes heating the superconducting switch to a target temperature higher than a critical temperature of the superconducting switch. Further, the method includes applying a voltage across the superconducting switch to energize the superconducting magnet, wherein self-joule heating of the superconducting switch maintains the target temperature. Moreover, the method includes gradually reducing the voltage across the superconducting switch such that a temperature of the superconducting switch is gradually reduced during energization of the superconducting magnet.

In an embodiment, the method may also include adjusting the voltage across the superconducting switch in a non-linear or step-controlled manner.

These and other features, aspects and advantages of the present disclosure will become better understood with reference to the following description and appended claims. The accompanying drawings, which are incorporated in and constitute a part of this specification, illustrate embodiments of the present disclosure and, together with the description, serve to explain the principles of the present disclosure.

### BRIEF DESCRIPTION OF THE DRAWINGS

A full and enabling disclosure of the present disclosure, including the best mode thereof, directed to one of ordinary skill in the art, is set forth in the specification, which makes reference to the appended figures, in which:

FIG. 1 illustrates a perspective view of one embodiment of a superconducting magnet according to the present disclosure;

FIG. 2 illustrates a transparent, perspective view of one embodiment of the superconducting magnet of FIG. 1, particularly illustrating internal components of the superconducting magnet;

FIG. 3 illustrates perspective view of one embodiment of a superconducting switch of a superconducting magnet according to the present disclosure;

FIG. 4 illustrates detailed, perspective view of the superconducting switch of FIG. 3, particularly illustrating a superconducting winding and a thermal conduction member of the superconducting switch;

FIG. 5 illustrates detailed, perspective view of the superconducting switch of FIG. 4, particularly illustrating the superconducting winding and the thermal conduction member of the superconducting switch thermally coupled to a conductive rod;

FIG. 6 illustrates detailed, perspective view of another embodiment of the superconducting switch according to the present disclosure, particularly illustrating the superconducting winding and the thermal conduction member of the superconducting switch electrically coupled to a tube;

FIG. 7 illustrates detailed, perspective view of the superconducting switch of FIG. 5, particularly illustrating the cooling tank removed to depict details to the thermal conduction member of the superconducting switch;

FIG. 8 illustrates cross-sectional view of the thermal conduction member of the superconducting switch of FIG. 7 along line 8-8;

FIG. 9 illustrates another detailed, perspective view of the superconducting switch of FIG. 5, particularly illustrating various leads of the superconducting switch;

FIG. 10 illustrates a flow diagram of one embodiment of a method of energizing a superconducting magnet having a superconducting switch according to the present disclosure;

FIG. 11 illustrates a graph of one embodiment of thermal conductivity (y-axis) versus temperature (x-axis) of various metal materials according to the present disclosure;

FIG. 12 illustrates a graph of one embodiment of cooling power (y-axis) versus warm end temperature (x-axis) of various metal materials according to the present disclosure;

FIG. 13 illustrates a graph of switch temperature (y-axis) versus time (x-axis) according to the present disclosure; and

FIG. 14 illustrates a graph of various parameters during magnet ramp (y-axis) versus ramp time (x-axis) according to the present disclosure.

### DETAILED DESCRIPTION

Reference now will be made in detail to embodiments of the present disclosure, one or more examples of which are illustrated in the drawings. Each example is provided by way of explanation of the present disclosure, not limitation of the present disclosure. In fact, it will be apparent to those skilled in the art that various modifications and variations can be made in the present disclosure without departing from the scope of the present disclosure. For instance, features illustrated or described as part of one embodiment can be used with another embodiment to yield a still further embodiment. Thus, it is intended that the present disclosure covers such modifications and variations as come within the scope of the appended claims and their equivalents.

In general, the present disclosure is directed to a superconducting switch for a superconducting magnet wound with superconducting circuit in a bi-filar winding mode to achieve minimum inductance. In embodiment, for example, one end of a thermal conduction member of the superconducting switch is thermally bonded with the body of the switch and the other end of the thermal conduction member is thermally attached to a cryogenically-cooled heat sink. Further, the thermal conduction member is made of at least two layers, one layer is a thermally conductive metal sheet, whereas another layer is a thermally less conductive material and more rigid which serves as a mechanical support of the metal sheet. The coefficients of thermal expansion (CTE) of the two layers are relatively close. As such, the superconducting switch enables an optimized non-linear energization of the superconducting magnet and can also minimize the total consumption of cryogen during this energization process.

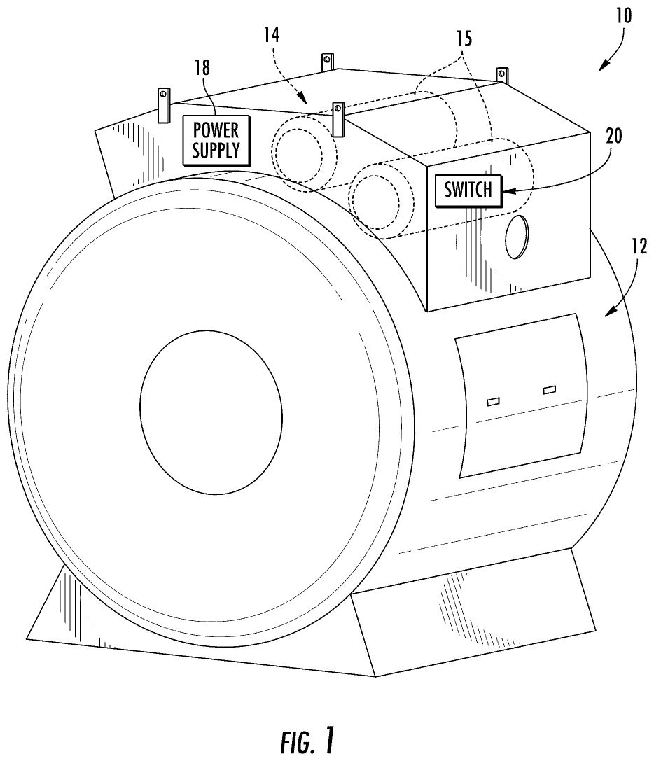

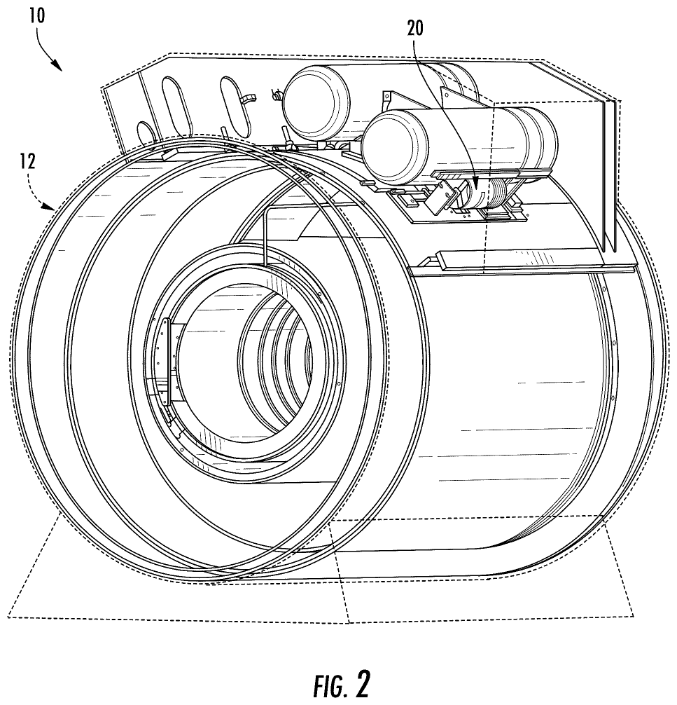

Referring now to the figures, FIGS. 1-3 illustrate perspective views of one embodiment of a superconducting magnet 10 according to the present disclosure. Such superconducting magnets are useful in a variety of applications, including but not limited to magnetic resonance imaging (MRI) machines, NMR spectrometers, generators, mass spectrometers, fusion reactors, particle accelerators, levitation, guidance, and propulsion, and similar. In particular, FIG. 1 illustrates an overall, perspective view of one embodiment of the superconducting magnet 10 according to the present disclosure; FIG. 2 illustrates a transparent, perspective view of one embodiment of the superconducting magnet 10 according to the present disclosure; and FIG. 3 illustrates an internal, perspective view of one embodiment of the superconducting magnet 10 according to the present disclosure.

In particular, as shown in FIG. 2, the superconducting magnet 10 includes a thermally-insulated container 12, which is generally referred to as a cryostat. As used herein, a cryostat generally refers to a vessel that contains a cryogenically cold system. Moreover, as shown in FIG. 3, the thermally-insulated container 12 of the superconducting magnet 10 includes at least one superconducting circuit 16 or coil inside the thermally-insulated container 12, supported by an internal structure 29. Accordingly, in such embodiments, the thermally-insulated container 12 insulates the superconducting circuit(s) 16 such that the wire(s) may be cooled to near absolute zero, e.g., to 10 Kelvin (K) and preferably to 4K. For example, as shown in FIG. 3, the thermally-insulated container 12 may include a plurality of conduits 21 that carry liquid helium from the tanks 15 to the internal structure 29 and/or throughout the outer wall of the thermally-insulated container 12. Furthermore, in an embodiment, the outer part of the thermally-insulated container 12 is a vacuum vessel that provides a thermal shield interposed between the outside environment and the cold components within the thermally-insulated container 12, thereby also minimizing radiation heat transfer.

More particularly, as shown, the superconducting circuit(s) 16 may be arranged in a coil shape and may be configured for generating a magnetic field. As shown particularly in FIG. 1, the superconducting magnet 10 further includes a power supply 18 connected to the superconducting circuit(s) 16 for energizing the superconducting circuit(s) 16.

Thus, in its superconducting state, the superconducting circuit(s) 16 do not have an electrical resistance and therefore can conduct much larger electric currents than ordinary wire, creating intense magnetic fields. Furthermore, during operation, the superconducting circuit(s) 16 must be cooled below their critical temperature, the temperature at which the wire material changes from the normal resistive state and becomes a superconductor. Typically, the superconducting circuit(s) 16 are cooled to temperatures significantly below their critical temperature, because the lower the temperature, the better superconductive windings work—the higher the currents and magnetic fields they can stand without returning to their non-superconductive state.

Thus, as shown in the embodiment of FIGS. 1-3, the superconducting magnet 10 may further include a cooling system 14 for providing liquid cooling to cool the superconducting circuit(s) 16. More specifically, as shown, the cooling system 14 may include one or more cooling tanks 15 containing a cooling medium 17 or coolant (FIG. 3). For example, in an embodiment, the cooling medium 17 may be liquid helium, which has a boiling point of 4.2 Kelvin that is far below the critical temperature of the wire materials.

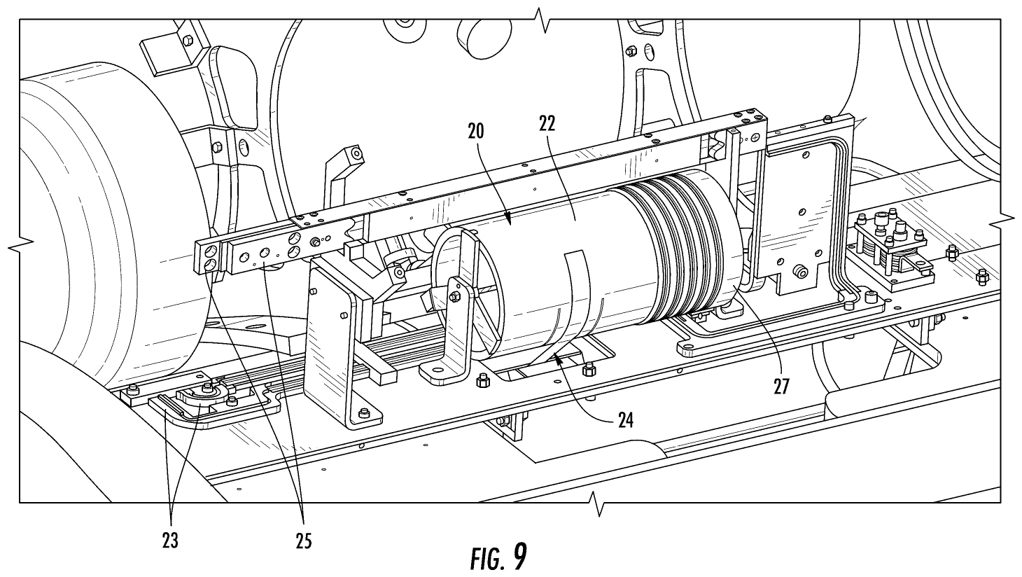

In one operating mode of the superconducting magnet 10, the superconducting circuit(s) 16 can be short-circuited with a piece of superconducting material once the magnet has been energized. In such embodiments, for example, the short circuit may be made by a superconducting switch 20, sometimes referred to as a persistent switch. In other words, the superconducting switch 20 generally refers to the piece of superconducting material inside the superconducting magnet 10 connected across the winding ends of the superconducting circuit(s) 16 with a heater that can raise its temperature above the transition temperature of the wire. In such embodiments, as shown in FIG. 9, leads 23, 25, 27 of the superconducting switch 20 may be electrically connected with current leads, which are electrically connected with the power supply 18 during an energization process. More specifically, as shown, leads 23 may be connected to the main windings, leads 27 may be connected to the superconducting switch 20, and leads 25 may be connected to the power supply, with the switch 20 electrically parallel with the main windings.

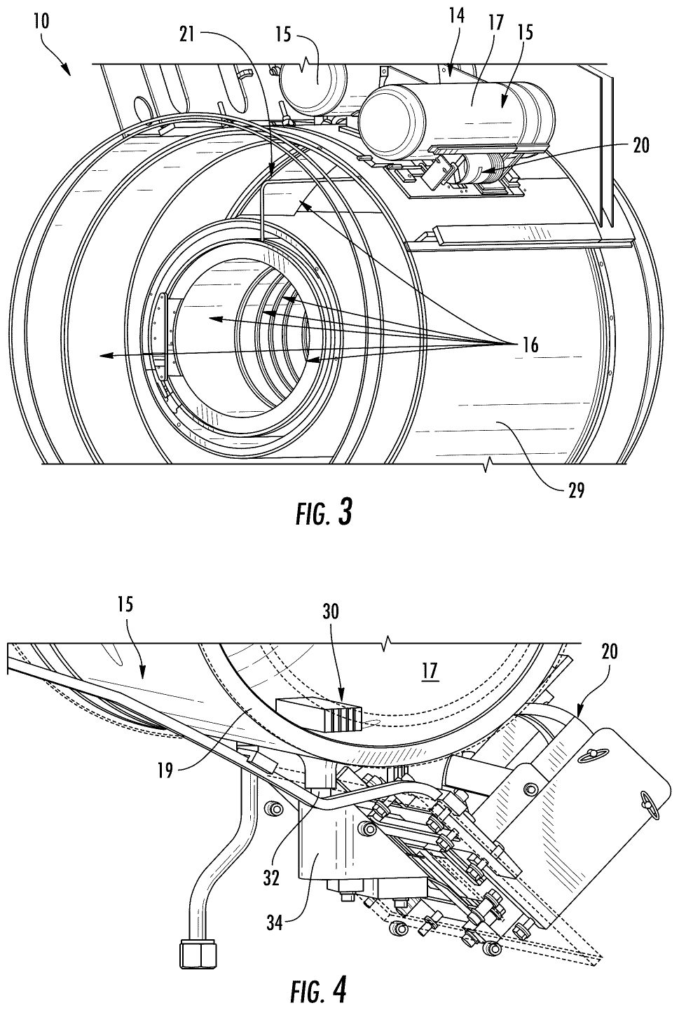

Further, as shown in FIG. 4, a heat exchanger 30, such as a finned-copper heat exchanger, may be included to allow the superconducting switch 20 to be cooled by the liquid helium. Thus, when the heat exchanger 30 is turned off and the superconducting switch 20 is cooled below its transition temperature, the superconducting circuit(s) 16 becomes a closed superconducting loop, so the power supply 18 can be turned off, and persistent currents will flow for long periods of time, preserving the magnetic field. Accordingly, an advantage of this persistent mode is that stability of the magnetic field is better than is achievable with the best power supplies, and no energy is needed to power the windings.

Moreover, when the superconducting magnet 10 is first turned on, the superconducting switch 20 is heated above its transition temperature, such that the superconducting switch 20 is resistive. The supply current is adjusted until the desired magnetic field is obtained, then the heater is turned off. The superconducting switch 20 cools to its superconducting temperature, thereby short-circuiting the superconducting circuit(s) 16. Then, the power supply 18 can be turned off.

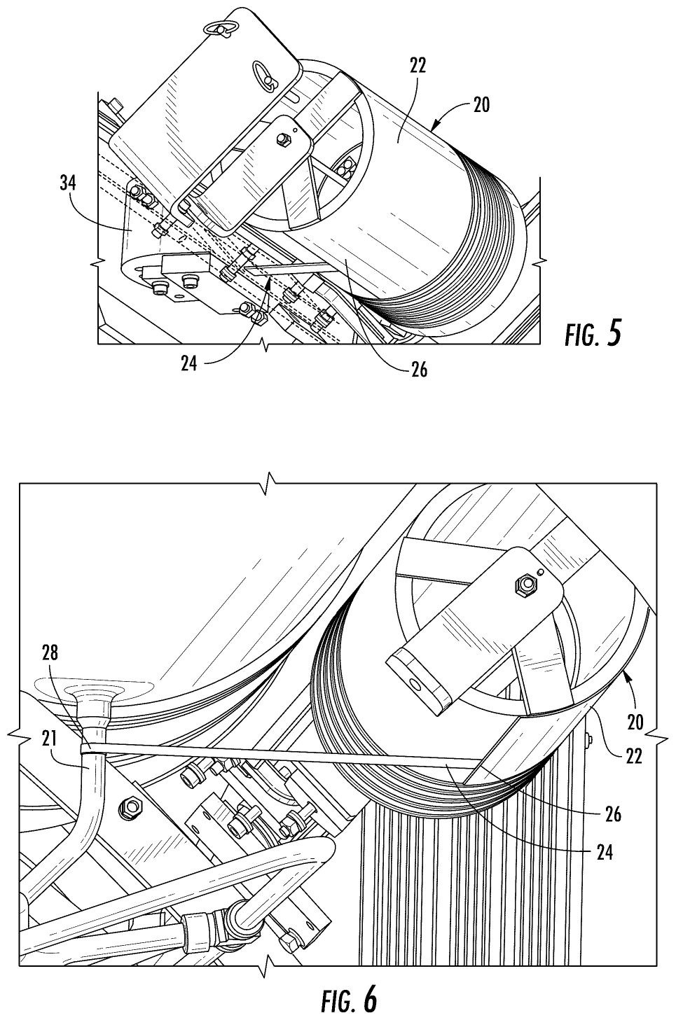

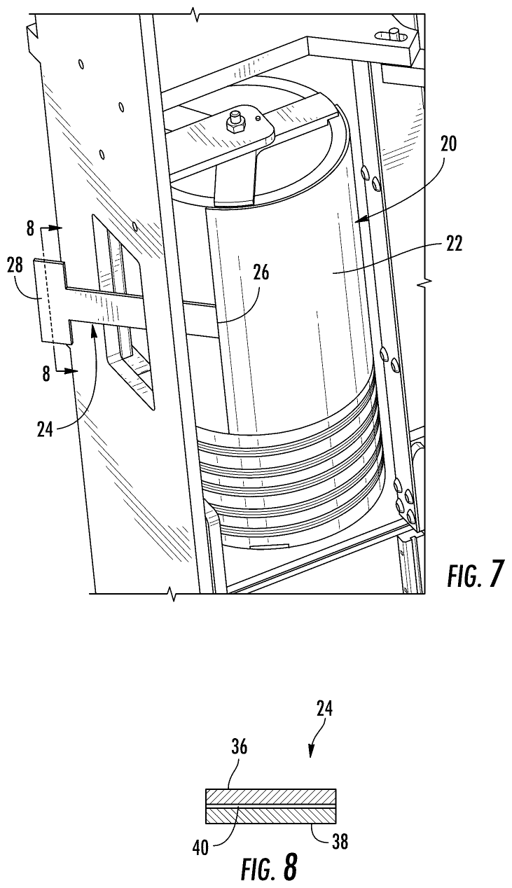

Referring now to FIGS. 4-7, the superconducting switch 20 includes a superconducting winding 22 and a thermal conduction member 24. For example, in an embodiment, the superconducting winding may be a bi-filar wound superconducting winding to achieve a minimum inductance. Further, in an embodiment, the thermal conduction member 24 includes a first end 26 thermally coupled to the superconducting winding 22 and a second end 28 thermally coupled to the cooling tank 15. For example, as shown in FIG. 4, the heat exchanger 30 may be mounted within the cooling tank 15 and thermally connected to the superconducting switch 20 by a thermally-conductive rod 32, such as copper rod, that is secured to a tank wall 19 of the cooling tank 15, e.g., via brazing. Furthermore, as shown in FIGS. 4 and 5, an additional support structure 34 may be mounted to the conductive rod 32, e.g., via soldering, to which the second end 28 of the thermal conduction member 24 can be secured. In alternative embodiments, as shown in FIG. 6, the thermal conduction member 24 may be mounted to one of the conduits 21. In such embodiments, the thermal conduction member 24 may be mounted to a conduit 21 using one or more braided copper straps, which may be secured to the thermal conduction member 24 and the conduit 21.

Referring now to FIG. 8, a cross-sectional view of the thermal conduction member 24 along line 8-8 is illustrated. In particular, as shown, the thermal conduction member 24 includes, at least, a first layer 36 and a second layer 38. The first layer 36 is constructed of a metal material having a first thermal conductivity. Moreover, as shown, the second layer 38 supports the first layer 36 and is constructed of a material having a second thermal conductivity that is lower than the first thermal conductivity. In addition, as shown, the second layer 38 may be bonded to the first layer 36 using an epoxy resin 40.

Further, in an embodiment, a coefficient of thermal expansion (CTE) of the second layer 38 is substantially equal to the CTE of the first layer 36, e.g., within plus or minus 10%. Moreover, in an embodiment, the second layer 38 has a higher tensile strength than the first layer 36. In additional embodiments, the metal material of the first layer 36 may be constructed of a high-purity metal material with a purity of greater than 99.99%. For example, in an embodiment, the high-purity metal material may be annealed, high-purity aluminum. In alternative embodiments, the first layer 36 may be constructed of tungsten or platinum. In another embodiment, the material of the second layer 38 may be an alloy of the metal material of the first layer 36.

Accordingly, in certain embodiments, the first thermal conductivity of the first layer 36 in a first temperature range of less than 40 Kelvin (K) (such as between about 15K to about 30K) may be at least three times greater than the first thermal conductivity of the first layer 36 in a second temperature range of greater than 50 K (such as between about 50K and about 60K). In such embodiments, the second temperature range includes temperatures when the superconducting switch 20 is maintained electrically resistive during an initial phase of a magnet energization process. In another embodiment, the first temperature range includes temperatures equal to about one third to one half of the second temperature range.

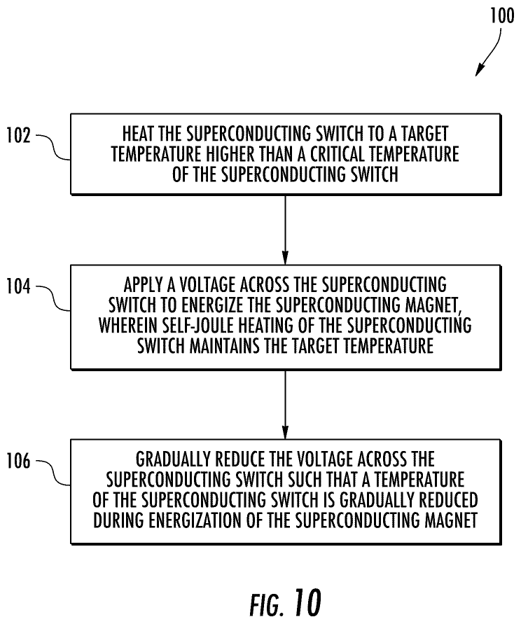

Referring now to FIG. 10, a flow diagram of one embodiment of a method 100 of energizing a superconducting magnet having a superconducting switch according to the present disclosure is illustrated. In general, the method 100 will be described herein with reference to the superconducting magnet 10 and the superconducting switch 20 described above with reference to FIGS. 1-9. However, it should be appreciated by those of ordinary skill in the art that the disclosed method 100 may generally be utilized with any superconducting magnet having any suitable configuration. In addition, although FIG. 10 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present disclosure.

As shown at (102), the method 100 includes heating the superconducting switch 20 to a target temperature higher than a critical temperature of the superconducting switch 20. As shown at (104), the method 100 includes applying a voltage across the superconducting switch 20 to energize the superconducting magnet 10, wherein self-joule heating of the superconducting switch 20 maintains the target temperature. As shown at (106), the method 100 includes gradually reducing the voltage across the superconducting switch 20 such that a temperature of the superconducting switch 20 is gradually reduced during energization of the superconducting magnet 10. In an embodiment, the method 100 may also include adjusting the voltage across the superconducting switch in a non-linear or step-controlled manner.

Accordingly, the superconducting switch 20 of the present disclosure enables an optimized non-linear energization of the superconducting magnet 10, which can also minimize the total consumption of cryogen during this energization process. In particular, as shown in FIGS. 11-14, various graphs are provided to further illustrate advantages of the present disclosure. FIG. 11 illustrates a graph 200 of thermal conductivity (y-axis) versus temperature (x-axis) of various metal materials according to the present disclosure. In particular, as shown, the superconducting switch 20 constructed of annealed, high-purity aluminum cools the switch gradually during the nonlinear ramp process (e.g., curve 202) as compared to other materials (e.g., 204, 206, 208). Further, in such embodiments, no latch cryogenic valve is needed for switch cooling.

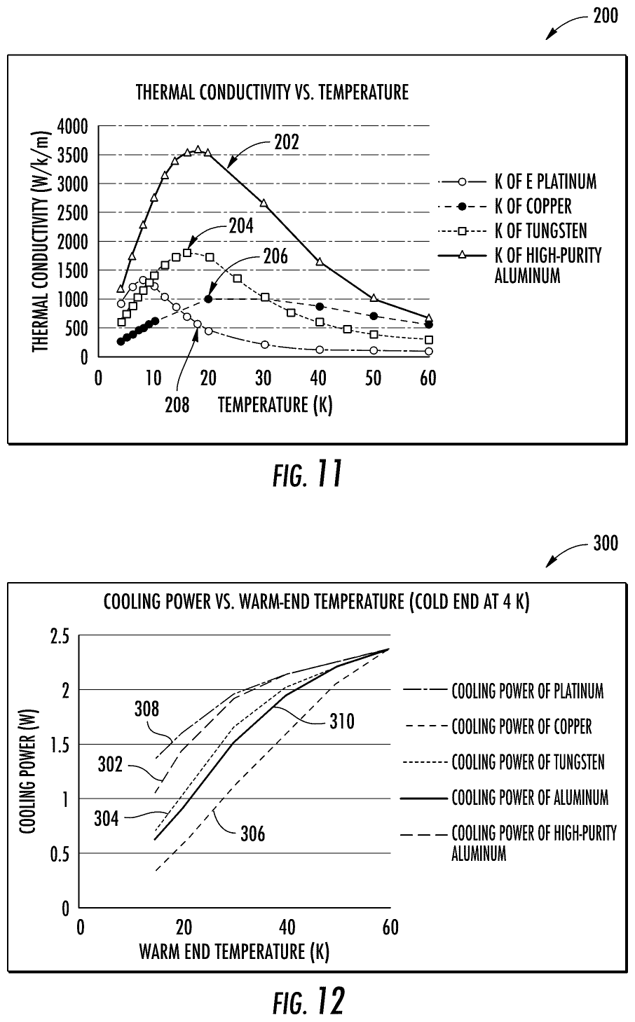

FIG. 12 illustrates a graph 300 of cooling power (y-axis) versus warm end temperature (x-axis) of various metal materials according to the present disclosure. In particular, as shown, the superconducting switch 20 constructed of annealed, high-purity aluminum (curve 302) has higher integral cooling power than copper (curve 306), particularly in the lower temperature range (from about 15 K to about 30 K) for closing the switch and parking the magnet 10. Curves 304, 308, and 310 are provided for further comparison of tungsten, platinum, and aluminum, respectively.

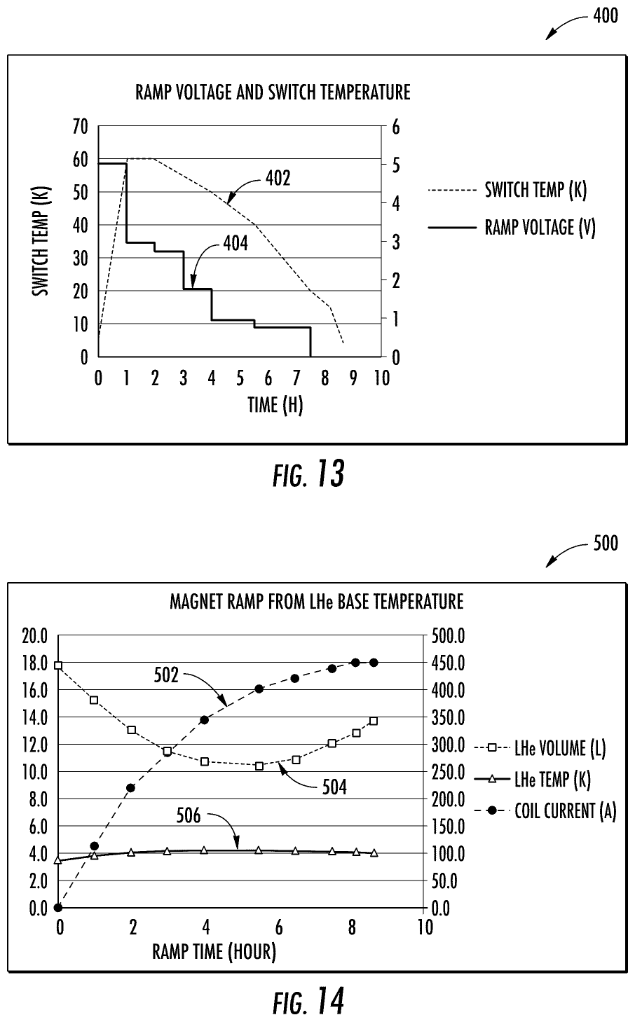

FIG. 13 illustrates a graph 400 of switch temperature (y-axis) versus time (x-axis) according to the present disclosure. In particular, as shown, the graph 400 illustrates the non-linear ramp profile of the voltage 402 as compared with the switch temperature 404. FIG. 14 illustrates a graph 500 of various parameters during magnet ramp (y-axis) versus ramp time (x-axis) according to the present disclosure. In particular, as shown, the graph 500 illustrates the coil current 502, the liquid helium volume used 504, and the liquid helium temperature 506.

Various aspects and embodiments of the present invention are defined by the following numbered clauses:
Clause 1. A superconducting magnet, comprising:
   a cooling tank containing a cooling medium;
   at least one superconducting circuit configured for generating a magnetic field;
   a power supply connected to the at least one superconducting circuit for energizing the at least one superconducting circuit; and
   a superconducting switch electrically connected across ends of the at least one superconducting circuit, the superconducting switch comprising:
   a superconducting winding; and
   a thermal conduction member having a first end thermally coupled to the superconducting winding and a second end thermally coupled to the cooling medium within the cooling tank, the thermal conduction member comprising, at least, a first layer and a second layer, the first layer being constructed of a metal material having a first thermal conductivity, the second layer supporting the first layer and being constructed of a material having a second thermal conductivity that is lower than the first thermal conductivity.
Clause 2. The superconducting magnet of clause 1, wherein the superconducting winding of the superconducting switch is a bi-filar wound superconducting winding.
Clause 3. The superconducting magnet of clauses 1-2, wherein a coefficient of thermal expansion (CTE) of the second layer is substantially equal to the CTE of the first layer.
Clause 4. The superconducting magnet of clause 3, wherein the second layer has a higher tensile strength than the first layer.
Clause 5. The superconducting magnet of any of the preceding clauses, wherein the second layer is bonded to the first layer using an epoxy resin.
Clause 6. The superconducting magnet of any of the preceding clauses, wherein the metal material of the first layer is constructed of a high-purity metal material with a purity of greater than 99.99%.
Clause 7. The superconducting magnet of clause 6, wherein the high-purity metal material comprises annealed, high-purity aluminum.
Clause 8. The superconducting magnet of any of the preceding clauses, wherein the first layer is constructed of one of tungsten or platinum.
Clause 9. The superconducting magnet of any of the preceding clauses, wherein the material of the second layer is an alloy of the metal material of the first layer.
Clause 10. The superconducting magnet of any of the preceding clauses, wherein the first thermal conductivity of the first layer in a first temperature range of less than 40 Kelvin is at least three times greater than the first thermal conductivity of the first layer in a second temperature range of greater than 50 Kelvin.
Clause 11. The superconducting magnet of clause 10, wherein the second temperature range comprises temperatures when the superconducting switch is maintained electrically resistive during an initial phase of a magnet energization process.
Clause 12. The superconducting magnet of clause 10, wherein the first temperature range comprises temperatures equal to about one third to one half of the second temperature range.
Clause 13. The superconducting magnet of any of the preceding clauses, wherein the superconducting switch comprises one or more leads electrically connected with current leads, the current leads being electrically connected with the power supply during an energization process.
Clause 14. The superconducting magnet of any of the preceding clauses, wherein the superconducting magnet is part of one of a magnetic resonance imaging (MRI) machine or a generator.
Clause 15. A superconducting switch for electrically connecting ends of at least one superconducting circuit of a superconducting magnet, the superconducting switch comprising:
   a superconducting winding; and
   a thermal conduction member having a first end thermally coupled to the superconducting winding and a second end thermally coupled to a cooling tank, the thermal conduction member comprising, at least, a first layer and a second layer, the first layer being constructed of a metal material having a first thermal conductivity, the second layer supporting the first layer and being constructed of a material having a second thermal conductivity that is lower than the first thermal conductivity.
Clause 16. A method of energizing a superconducting magnet having a superconducting switch, the superconducting switch having a superconducting winding and a thermal conduction member with a first end thermally coupled to the superconducting winding and a second end thermally coupled to a cooling tank of the superconducting magnet, the thermal conduction member constructed of a first layer and a second layer, the first layer formed of a metal material having a first thermal conductivity, the second layer supporting the first layer and formed of a material having a second thermal conductivity that is lower than the first thermal conductivity, the method comprising:
   heating the superconducting switch to a target temperature higher than a critical temperature of the superconducting switch;
   applying a voltage across the superconducting switch to energize the superconducting magnet, wherein self-joule heating of the superconducting switch maintains the target temperature; and
   gradually reducing the voltage across the superconducting switch such that a temperature of the superconducting switch is gradually reduced during energization of the superconducting magnet.
Clause 17. The method of clause 16, further comprising adjusting the voltage across the superconducting switch in a non-linear or step-controlled manner.
Clause 18. The method of clauses 16-17, wherein a coefficient of thermal expansion (CTE) of the second layer is substantially equal to the CTE of the first layer, wherein the second layer has a higher tensile strength than the first layer.
Clause 19. The method of clauses 16-18, wherein the first thermal conductivity of the first layer in a first temperature range of less than 40 Kelvin is at least three times greater than the first thermal conductivity of the first layer in a second temperature range of greater than 50 Kelvin.
Clause 20. The method of clause 19, wherein the second temperature range comprises temperatures when the superconducting switch is maintained electrically resistive during an initial phase of a magnet energization process, and wherein the first temperature range comprises temperatures equal to about one third to one half of the second temperature range.

This written description uses examples to disclose the present disclosure, including the best mode, and also to enable any person skilled in the art to practice the present disclosure, including making and using any devices or systems and performing any incorporated methods. The patentable scope of the present disclosure is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A superconducting magnet, comprising:
a cooling tank containing a cooling medium;
at least one superconducting circuit configured for generating a magnetic field;
a power supply connected to the at least one superconducting circuit for energizing the at least one superconducting circuit; and
a superconducting switch electrically connected across ends of the at least one superconducting circuit, the superconducting switch comprising:
a superconducting winding; and
a thermal conduction member having a first end thermally coupled to the superconducting winding and a second end thermally coupled to the cooling medium within the cooling tank, the thermal conduction member comprising, at least, a first layer and a second layer, the first layer being constructed of a metal material having a first thermal conductivity, the second layer supporting the first layer and being constructed of a material having a second thermal conductivity that is lower than the first thermal conductivity.

2. The superconducting magnet of claim 1, wherein the superconducting winding of the superconducting switch is a bi-filar wound superconducting winding.

3. The superconducting magnet of claim 1, wherein a coefficient of thermal expansion (CTE) of the second layer is substantially equal to the CTE of the first layer.

4. The superconducting magnet of claim 3, wherein the second layer has a higher tensile strength than the first layer.

5. The superconducting magnet of claim 1, wherein the second layer is bonded to the first layer using an epoxy resin.

6. The superconducting magnet of claim 1, wherein the metal material of the first layer is constructed of a high-purity metal material with a purity of greater than 99.99%.

7. The superconducting magnet of claim 6, wherein the high-purity metal material comprises annealed, high-purity aluminum.

8. The superconducting magnet of claim 1, wherein the first layer is constructed of one of tungsten or platinum.

9. The superconducting magnet of claim 1, wherein the material of the second layer is an alloy of the metal material of the first layer.

10. The superconducting magnet of claim 1, wherein the first thermal conductivity of the first layer in a first temperature range of less than 40 Kelvin is at least three times greater than the first thermal conductivity of the first layer in a second temperature range of greater than 50 Kelvin.

11. The superconducting magnet of claim 10, wherein the second temperature range comprises temperatures when the superconducting switch is maintained electrically resistive during an initial phase of a magnet energization process.

12. The superconducting magnet of claim 10, wherein the first temperature range comprises temperatures equal to about one third to one half of the second temperature range.

13. The superconducting magnet of claim 1, wherein the superconducting switch comprises one or more leads electrically connected with current leads, the current leads being electrically connected with the power supply during an energization process.

14. The superconducting magnet of claim 1, wherein the superconducting magnet is part of one of a magnetic resonance imaging (MRI) machine or a generator.

15. A superconducting switch for electrically connecting ends of at least one superconducting circuit of a superconducting magnet, the superconducting switch comprising:
a superconducting winding; and
a thermal conduction member having a first end thermally coupled to the superconducting winding and a second end thermally coupled to a cooling tank, the thermal conduction member comprising, at least, a first layer and a second layer, the first layer being constructed of a metal material having a first thermal conductivity, the second layer supporting the first layer and being constructed of a material having a second thermal conductivity that is lower than the first thermal conductivity.

16. A method of energizing a superconducting magnet having a superconducting switch, the superconducting switch having a superconducting winding and a thermal conduction member with a first end thermally coupled to the superconducting winding and a second end thermally coupled to a cooling tank of the superconducting magnet, the thermal conduction member constructed of a first layer and a second layer, the first layer formed of a metal material having a first thermal conductivity, the second layer supporting the first layer and formed of a material having a second thermal conductivity that is lower than the first thermal conductivity, the method comprising:
heating the superconducting switch to a target temperature higher than a critical temperature of the superconducting switch;
applying a voltage across the superconducting switch to energize the superconducting magnet, wherein self-joule heating of the superconducting switch maintains the target temperature; and
gradually reducing the voltage across the superconducting switch such that a temperature of the superconducting switch is gradually reduced during energization of the superconducting magnet.

17. The method of claim 16, further comprising adjusting the voltage across the superconducting switch in a non-linear or step-controlled manner.

18. The method of claim 16, wherein a coefficient of thermal expansion (CTE) of the second layer is substantially equal to the CTE of the first layer, wherein the second layer has a higher tensile strength than the first layer.

19. The method of claim 16, wherein the first thermal conductivity of the first layer in a first temperature range of less than 40 Kelvin is at least three times greater than the first thermal conductivity of the first layer in a second temperature range of greater than 50 Kelvin.

20. The method of claim 19, wherein the second temperature range comprises temperatures when the superconducting switch is maintained electrically resistive during an initial phase of a magnet energization process, and wherein the first temperature range comprises temperatures equal to about one third to one half of the second temperature range.
